(19) United States
(12) Patent Application Publication
(10) Pub. No.: US 2026/0302503 A1
(43) Pub. Date: Oct. 1, 2026

(54) BATTERY PACK

(71) Applicant: HONDA MOTOR CO., LTD., Tokyo (JP)

(72) Inventor: Soichi MORII, Saitama (JP)

(73) Assignee: HONDA MOTOR CO., LTD., Tokyo (JP)

(21) Appl. No.: 19/577,416

(22) Filed: Mar. 25, 2026

(30) Foreign Application Priority Data
Mar. 27, 2025 (JP) 2025-053616

(51) Int. Cl. H01M 50/298; H01M 10/48; H01M 50/211; H01M 50/284; H01M 50/51; H01M 50/519; H05K 1/02

(52) U.S. Cl. CPC H01M 50/298; H01M 10/482; H01M 50/211; H01M 50/284; H01M 50/51; H01M 50/519; H05K 1/0296

(57) ABSTRACT

A battery pack includes a battery including plural cells; a detection unit; and a wiring group as defined herein, the wiring group includes a first wiring group connected to a potential detection location located on a first side of the laminate of the plural cells, among plural potential detection locations that are one end and other end of series connection of the plural cells, and a midpoint between the cells that are adjacent in a connection order, and a second wiring group connected to a potential detection location located on a second side of the laminate, the circuit board includes a first printed circuit that electrically connects the first wiring group and the integrated circuit and a second printed circuit that electrically connects the second wiring group and the integrated circuit, and the first and second printed circuits are provided on different pattern forming surfaces of the circuit board.

### CROSS-REFERENCE TO RELATED APPLICATION

This application is based on and claims priority under 35 USC 119 from Japanese Patent Application No. 2025-053616 filed on Mar. 27, 2025.

### TECHNICAL FIELD

The present invention relates to a battery pack.

### BACKGROUND ART

In recent years, researches and developments have been conducted on a secondary battery which contributes to improvement in energy efficiency in order to allow more people to have access to affordable, reliable, sustainable and advanced energy.

A battery module disclosed in Patent Literature 1 is a battery module to be mounted on an electric vehicle or the like and includes a laminate of a plurality of cells and a sensor apparatus for detecting a voltage of each cell. The plurality of cells are laminated such that positive electrode terminals and negative electrode terminals are inverted left and right sequentially. A positive electrode terminal of one cell adjacent in a lamination direction of the plurality of cells is connected to a negative electrode terminal of another cell by a bus bar, and the plurality of cells are connected in series by a plurality of bus bars. The sensor apparatus is disposed on an upper surface of the cell laminate.

One end of a voltage detection line is connected to each bus bar, and the other end of a cable that bundles a plurality of voltage detection lines is provided with a cable-side connector. The cable-side connector is connected to a sensor-side connector provided on one side surface of the sensor apparatus, and a potential of each bus bar is received by the sensor apparatus. Typically, the sensor apparatus detects the voltage of each cell based on a potential difference between two bus bars that are adjacent to each other in an arrangement order of bus bars connected in series.

Patent Literature 1: JP6670348B

### SUMMARY OF INVENTION

The plurality of bus bars are alternately disposed on a left side and a right side of the cell laminate. On a bus bar connection side of the cable that connects the plurality of bus bars to the sensor apparatus, the plurality of voltage detection lines are alternately routed on the left side and the right side of the cell laminate. However, since the sensor-side connector is provided on the one side surface of the sensor apparatus, the plurality of voltage detection lines are bundled on a sensor apparatus connection side of the cable. As the number of laminated cells increases, the cable becomes bulkier, which may lead to difficulty in handling the cable.

An object of the present invention is to enable efficient connection between a plurality of cells and a detection unit that detects a voltage of each cell.

A battery pack according to an aspect of the present invention includes:
a battery including a plurality of cells connected in series;
a detection unit including an integrated circuit that detects a voltage of each of the plurality of cells, and a circuit board where the integrated circuit is mounted; and
a wiring group configured to connect the battery and the detection unit, in which
each of the plurality of cells is flat, has a positive electrode at one end in a first direction orthogonal to a thickness direction, and has a negative electrode at the other end in the first direction,
the plurality of cells are laminated in the thickness direction with the first direction of each of the cells aligned in parallel, and are laminated such that disposition of the positive electrode and the negative electrode of each of the cells is alternately inverted,
the detection unit is disposed adjacent to a laminate of the plurality of cells in a second direction orthogonal to the thickness direction and the first direction, or is laminated together with the plurality of cells,
the wiring group includes
   a first wiring group connected to a potential detection location located on a first side in the first direction of the laminate of the plurality of cells, among a plurality of potential detection locations that are one end and the other end of series connection of the plurality of cells, and a midpoint between the cells that are adjacent in a connection order, and
   a second wiring group connected to a potential detection location located on a second side opposite from the first side in the first direction of the laminate of the plurality of cells, among the plurality of potential detection locations,
the circuit board includes
   a first printed circuit that electrically connects the first wiring group and the integrated circuit, and
   a second printed circuit that electrically connects the second wiring group and the integrated circuit,
the first printed circuit and the second printed circuit are provided on different pattern forming surfaces of the circuit board,
the first printed circuit extends to the first side in the first direction of the circuit board, and
the second printed circuit extends to the second side in the first direction of the circuit board.

It is possible to efficiently connect a plurality of cells to a detection unit that detects a voltage of each cell.

### BRIEF DESCRIPTION OF DRAWINGS

FIG. 1 is a circuit diagram of an example of a battery pack for showing an embodiment of the present invention.

FIG. 2 is a perspective view schematically showing disposition and connection of a plurality of cells.

FIG. 3 is a perspective view showing an example of a detection unit.

FIG. 4 is a plan view of the detection unit in FIG. 3.

FIG. 5 is a cross-sectional view of the detection unit in FIG. 4.

FIG. 6 is a perspective view showing a modification of the detection unit in FIG. 3.

FIG. 7 is a plan view of the detection unit in FIG. 6.

FIG. 8 is a perspective view showing another example of the detection unit.

FIG. 9 is a cross-sectional view of the detection unit in FIG. 8.

FIG. 10 is a cross-sectional view of a modification of the detection unit in FIG. 8.

### DESCRIPTION OF EMBODIMENTS

An example of a battery pack for describing an embodiment of the present invention will be described with reference to the accompanying drawings.

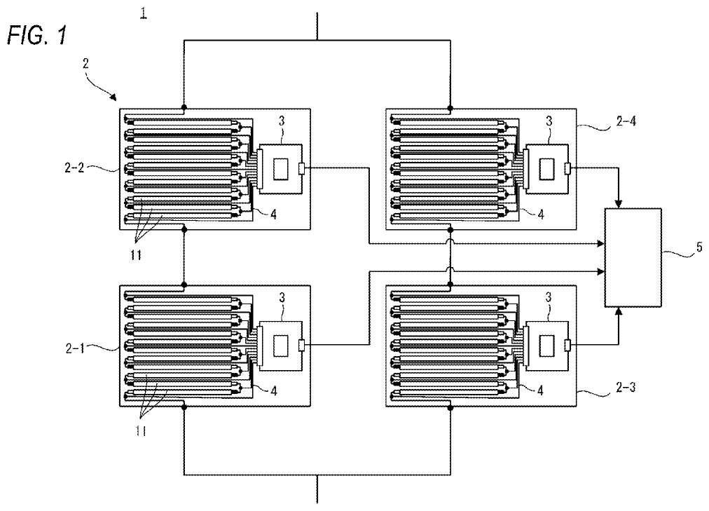

A battery pack 1 shown in FIG. 1 includes a battery 2 including a plurality of cells 11, a detection unit 3 that detects a voltage of each of the plurality of cells 11, a wiring group 4 that connects the battery 2 and the detection unit 3, and a battery electronic control unit (ECU) 5. The battery ECU 5 estimates, for example, a state of charge (SOC) of the battery 2 based on the voltage of each of the plurality of cells 11 detected by the detection unit 3.

The plurality of cells 11 are modularized, and are divided into four modules, that is, a first module 2-1, a second module 2-2, a third module 2-3, and a fourth module 2-4 in the shown example. In each module, the plurality of cells 11 are connected in series. In the shown example, the first module 2-1 and the second module 2-2 are connected in series, and the third module 2-3 and the fourth module 2-4 are also connected in series.

The detection unit 3 and the wiring group 4 are provided for each module. For example, the wiring group 4 for the first module 2-1 connects the first module 2-1 and the detection unit 3 for the first module 2-1. The detection unit 3 for the first module 2-1 detects the voltage of each cell 11 in the first module 2-1.

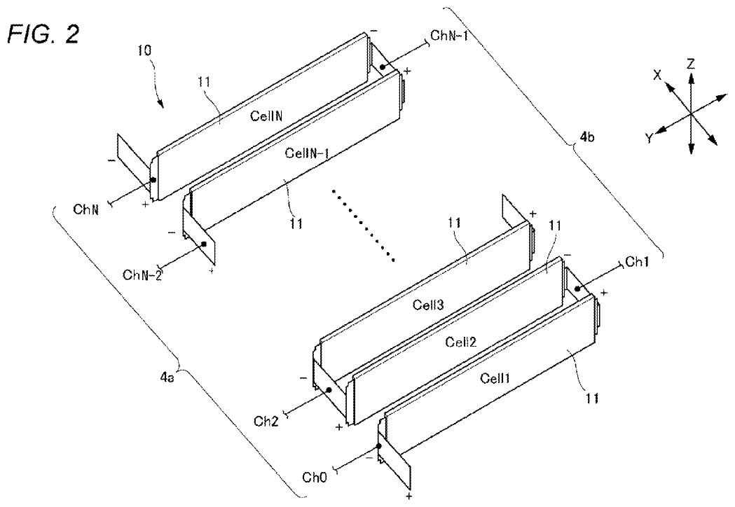

FIG. 2 shows disposition and connection of the plurality of cells 11 in one module. In the example shown in FIG. 2, one module includes N cells 11, and the N cells 11 are connected in series. The number of cells is appropriately set based on a voltage required for the module.

Each cell 11 is, for example, a lithium ion battery or a nickel-metal hydride battery using a liquid electrolyte, or an all-solid-state battery using a solid electrolyte. The cell 11 shown in FIG. 2 is a so-called laminate cell in which a positive electrode, a negative electrode, a separator, and an electrolyte are sealed in a laminate film pack.

The cell 11 has a flat shape, has the positive electrode at one end in a Y direction orthogonal to an X direction that is a thickness direction, and has the negative electrode at the other end in the Y direction. The plurality of cells 11 are laminated in the X direction by aligning the Y direction of each cell and alternately inverting disposition of the positive electrode and the negative electrode of each cell. In a cell laminate 10 in which the plurality of cells 11 are laminated, a positive electrode tab and a negative electrode tab of two adjacent cells 11 are directly welded, for example, and the plurality of cells 11 are connected in series.

The detection unit 3 acquires potentials of one end and the other end of the series connection of the plurality of cells 11 and a midpoint between cells adjacent to each other in a connection order. In the present example in which N cells are connected in series, the detection unit 3 detects a potential at one end as Ch0, potentials at midpoints between cells adjacent to each other in the connection order as Ch1, Ch2, . . . , in order from the one end side, and a potential at the other end as ChN. Then, the detection unit 3 uses Ch0 as a reference potential, detects a voltage of a first cell on the one end side based on, for example, a potential difference between Ch0 and Ch1, and detects a voltage of a next second cell based on a potential difference between Ch1 and Ch2.

One end of each line of the wiring group 4 is connected to any potential detection location. Assuming that N is an even number, potential detection locations (Ch0, Ch2, Ch4, . . . , ChN) arranged every other location from Ch0 are located on a first side in the Y direction of the cell laminate 10, and a plurality of lines connected to these potential detection locations constitute a first wiring group 4a. Potential detection locations (Ch1, Ch3, Ch5, . . . , ChN-1) arranged every other location from Ch1 are located on a second side in the Y direction of the cell laminate 10, and a plurality of lines connected to these potential detection locations constitute a second wiring group 4b.

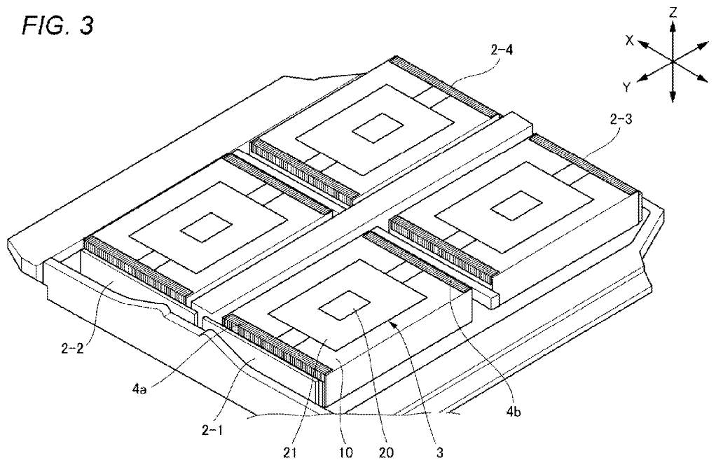

FIG. 3 shows an example of the detection unit 3. The detection unit 3 is disposed adjacent to the cell laminate 10 in a Z direction orthogonal to the X direction and the Y direction. The detection unit 3 includes an integrated circuit 20 and a circuit board 21 where the integrated circuit 20 is mounted, and the circuit board 21 is disposed along one surface of the cell laminate 10 facing the Z direction.

The first wiring group 4a located on the first side in the Y direction of the cell laminate 10 is routed along an outer surface on the first side of the cell laminate 10 and connected to an end on the first side of the circuit board 21. The second wiring group 4b located on the second side in the Y direction of the cell laminate 10 is routed along an outer surface on the second side of the cell laminate 10 and connected to an end on the second side of the circuit board 21. The first wiring group 4a and the second wiring group 4b may be cables obtained by bundling individual wires, and are preferably ribbon cables having a flat shape or formed on a flexible printed circuit board.

The integrated circuit 20 receives potentials of the potential detection locations (Ch0, Ch1, Ch2, . . . , ChN) of the cell laminate 10 via the first wiring group 4a, the second wiring group 4b, and a printed circuit formed on the circuit board 21. The integrated circuit 20 detects the voltage of each cell 11 of the cell laminate 10 based on the received potentials.

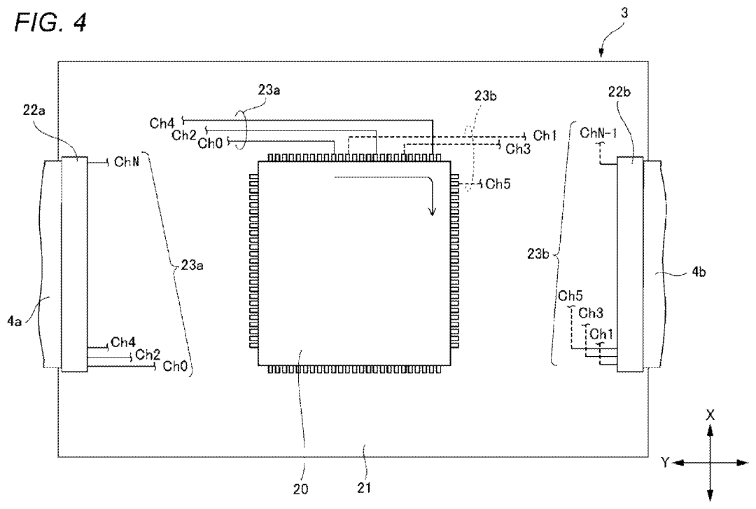

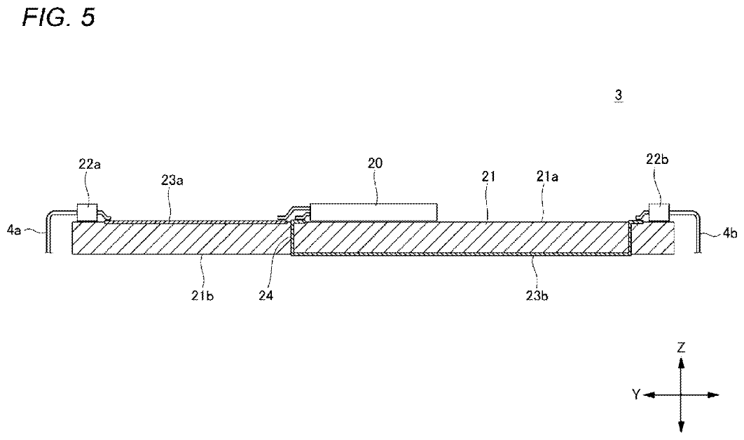

As shown in FIGS. 4 and 5, the integrated circuit 20 is disposed at a central portion of a first surface 21a that is one surface of the circuit board 21. The integrated circuit 20 includes a plurality of terminals, and the plurality of terminals are provided aligned on an outer periphery of a package of the integrated circuit 20. The potentials of the potential detection locations (Ch0, Ch1, Ch2, . . . , ChN) of the cell laminate 10 are received by any terminal of the integrated circuit 20. Typically, potential input terminals are arranged in an order of Ch0, Ch1, Ch2, . . . , ChN, starting from a potential input terminal where the potential of Ch0 is received.

A first connector 22a is provided at the end on the first side in the Y direction of the circuit board 21, and the first wiring group 4a connected to the potential detection locations (Ch0, Ch2, Ch4, . . . , ChN) arranged every other location from Ch0 is connected to the first connector 22a. The circuit board 21 includes a first printed circuit 23a that connects each terminal of the first connector 22a and a corresponding potential input terminal of the integrated circuit 20. A second connector 22b is provided at the end on the second side in the Y direction of the circuit board 21, and the second wiring group 4b connected to the potential detection locations (Ch1, Ch3, Ch5, . . . , ChN-1) arranged every other location from Ch1 is connected to the second connector 22b. The circuit board 21 includes a second printed circuit 23b that connects each terminal of the second connector 22b and a corresponding potential input terminal of the integrated circuit 20.

The first printed circuit 23a and the second printed circuit 23b are provided on different pattern forming surfaces of the circuit board 21. In the example shown in FIG. 5, the first printed circuit 23a is provided on the first surface 21a of the circuit board 21 where the integrated circuit 20 is mounted, extends toward the first side in the Y direction of the circuit board 21, and is connected to the first connector 22a. Meanwhile, the second printed circuit 23b is provided on a second surface 21b that is the other surface of the circuit board 21, extends toward the second side in the Y direction of the circuit board 21, and is connected to the second connector 22b. The integrated circuit 20 mounted on the first surface 21a of the circuit board 21 and the second printed circuit 23b provided on the second surface 21b of the circuit board 21 are connected through a plurality of vias 24 provided in the vicinity of the integrated circuit 20.

In FIG. 4, the first printed circuit 23a provided on the first surface 21a of the circuit board 21 is indicated by a solid line, and the second printed circuit 23b provided on the second surface 21b of the circuit board 21 is indicated by a broken line. Since the first printed circuit 23a and the second printed circuit 23b are provided on different pattern forming surfaces of the circuit board 21, an intersection between the first printed circuit 23a extending to the first side in the Y direction of the circuit board 21 and the second printed circuit 23b extending to the second side is eliminated. Accordingly, the first wiring group 4a located on the first side can be connected to the first side of the circuit board 21, the second wiring group 4b located on the second side can be connected to the second side of the circuit board 21 separately from the first wiring group 4a, and thus the cell laminate 10 and the detection unit 3 can be efficiently connected.

When the detection unit 3 is disposed adjacent to the cell laminate 10 in the Z direction, the second connector 22b is preferably provided on the first surface 21a of the circuit board 21 where the first connector 22a and the integrated circuit 20 are also provided. Accordingly, a size of the detection unit 3 in the Z direction can be reduced, and a height of the battery pack 1 can be reduced. When the second connector 22b is provided on the first surface 21a of the circuit board 21, the second connector 22b provided on the first surface 21a and the second printed circuit 23b provided on the second surface 21b are connected through the plurality of vias 24 provided in the vicinity of the second connector 22b.

When the first wiring group 4a and the second wiring group 4b are provided by a flexible printed circuit board, the flexible printed circuit board may be soldered to the circuit board 21 instead of using the first connector 22a and the second connector 22b from the viewpoint of cost reduction.

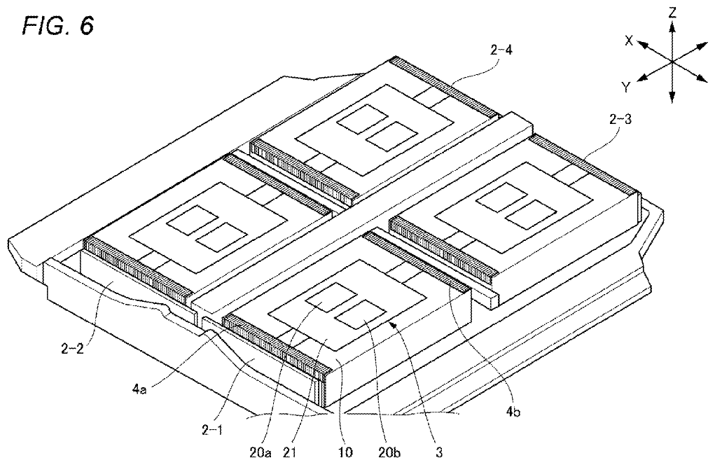

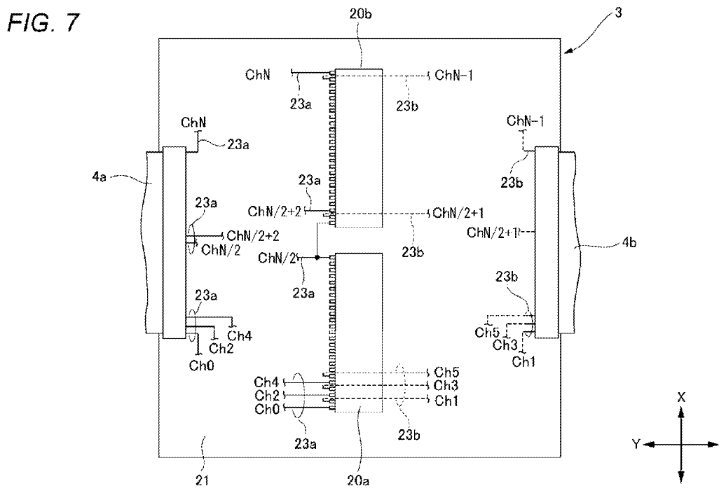

In the detection unit 3 shown in FIGS. 6 and 7, two integrated circuits, that is, a first integrated circuit 20a and a second integrated circuit 20b are used. When the number of potential input terminals is insufficient in one integrated circuit with respect to the number of cells 11 constituting the cell laminate 10, a plurality of integrated circuits are chain-connected to secure a required number of potential input terminals. The cell laminate 10 includes N cells 11 and has N+1 potential detection locations, that is, Ch0, Ch1, Ch2, . . . , ChN, whereas the first integrated circuit 20a and the second integrated circuit 20b each have N/2+1 potential input terminals.

Potentials of Ch0, Ch1, Ch2, . . . , ChN/2 are received by the potential input terminals of the first integrated circuit 20a in order from a terminal on the one end side. A potential input terminal on the other end side of the first integrated circuit 20a where the potential of ChN/2 is received is electrically connected to a potential input terminal on the one end side of the second integrated circuit 20b via the printed circuit of the circuit board 21. Potentials of ChN/2, ChN/2+1, ChN/2+2, . . . , ChN are received by the potential input terminals of the second integrated circuit 20b in order from a terminal on the one end side. Due to such chain connection, the first integrated circuit 20a and the second integrated circuit 20b function as one integrated circuit as a whole.

From the viewpoint of reducing the height of the battery pack 1, the first integrated circuit 20a and the second integrated circuit 20b are preferably mounted on the first surface 21a, which is one surface of the circuit board 21. The first integrated circuit 20a and the second integrated circuit 20b mounted on the first surface 21a of the circuit board 21 are equivalent to the single integrated circuit 20 shown in FIG. 4. Thus, the first printed circuit 23a that connects the first wiring group 4a to the first integrated circuit 20a and the second integrated circuit 20b is provided on the first surface 21a of the circuit board 21, extends toward the first side in the Y direction of the circuit board 21, and is connected to the first connector 22a. Meanwhile, the second printed circuit 23b is provided on the second surface 21b of the circuit board 21, extends toward the second side in the Y direction of the circuit board 21, and is connected to the second connector 22b.

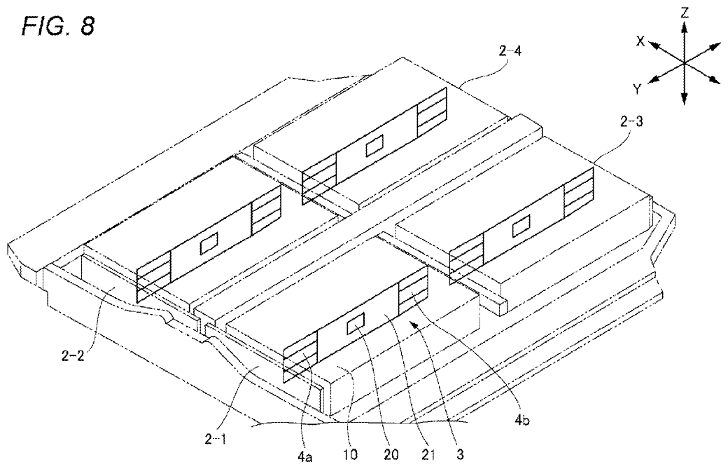

The detection unit 3 shown in FIG. 8 includes the integrated circuit 20 and the circuit board 21 where the integrated circuit 20 is mounted, and the circuit board 21 is laminated together with the plurality of cells 11 such that a thickness direction thereof is aligned with the X direction that is the thickness direction of the cells 11. In the example shown in FIG. 8, the detection unit 3 is disposed at a central portion in the X direction of the cell laminate 10.

The first wiring group 4a located on the first side in the Y direction of the cell laminate 10 is routed along a side surface of the cell laminate 10 on the first side facing the Y direction, drawn into the cell laminate 10 from the central portion in the X direction of the cell laminate 10, and connected to the end on the first side of the circuit board 21. The second wiring group 4b located on the second side in the Y direction of the cell laminate 10 is routed along a side surface of the cell laminate 10 on the second side facing the Y direction, drawn into the cell laminate 10 from the central portion in the X direction of the cell laminate 10, and connected to the end on the second side of the circuit board 21.

The integrated circuit 20 receives the potentials of the potential detection locations (Ch0, Ch1, Ch2, . . . , ChN) of the cell laminate 10 via the first wiring group 4a, the second wiring group 4b, and the printed circuit formed on the circuit board 21. The integrated circuit 20 detects the voltage of each cell 11 of the cell laminate 10 based on the received potentials.

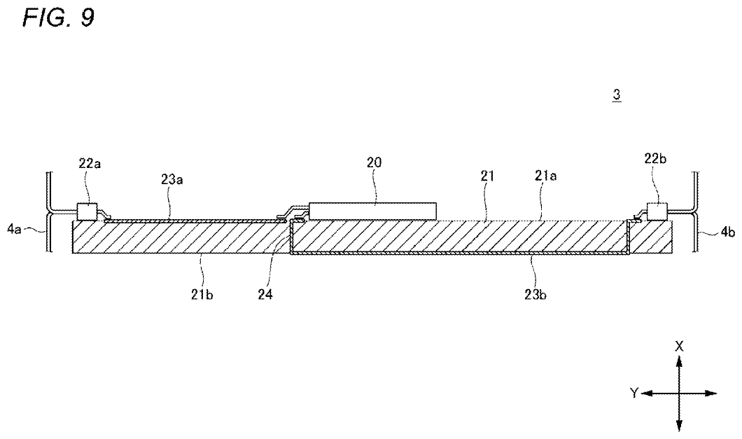

As shown in FIG. 9, the integrated circuit 20 is disposed at the central portion of the first surface 21a of the circuit board 21. The first connector 22a is provided at the end on the first side in the Y direction of the circuit board 21, and the first wiring group 4a connected to the potential detection locations (Ch0, Ch2, Ch4, . . . , ChN) arranged every other location from Ch0 is connected to the first connector 22a. The circuit board 21 includes the first printed circuit 23a that connects each terminal of the first connector 22a and the corresponding potential input terminal of the integrated circuit 20. The second connector 22b is provided at the end on the second side in the Y direction of the circuit board 21, and the second wiring group 4b connected to the potential detection locations (Ch1, Ch3, Ch5, . . . , ChN-1) arranged every other location from Ch1 is connected to the second connector 22b. The circuit board 21 includes the second printed circuit 23b that connects each terminal of the second connector 22b and the corresponding potential input terminal of the integrated circuit 20.

The first printed circuit 23a and the second printed circuit 23b are provided on different pattern forming surfaces of the circuit board 21. In the example shown in FIG. 9, the first printed circuit 23a is provided on the first surface 21a of the circuit board 21 where the integrated circuit 20 is mounted, extends toward the first side in the Y direction of the circuit board 21, and is connected to the first connector 22a. Meanwhile, the second printed circuit 23b is provided on the second surface 21b that is the other surface of the circuit board 21, extends toward the second side in the Y direction of the circuit board 21, and is connected to the second connector 22b.

Since the first printed circuit 23a and the second printed circuit 23b are provided on different pattern forming surfaces of the circuit board 21, an intersection between the first printed circuit 23a extending to the first side in the Y direction of the circuit board 21 and the second printed circuit 23b extending to the second side is eliminated. Accordingly, the first wiring group 4a located on the first side can be connected to the first side of the circuit board 21, the second wiring group 4b located on the second side can be connected to the second side of the circuit board 21 separately from the first wiring group 4a, and thus the cell laminate 10 and the detection unit 3 can be efficiently connected.

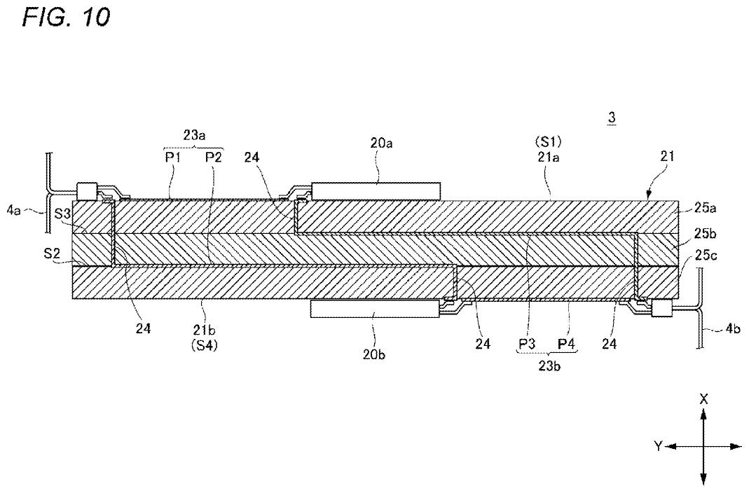

As shown in FIG. 10, two integrated circuits, that is, the first integrated circuit 20a and the second integrated circuit 20b can be used in the detection unit 3 laminated together with the plurality of cells 11. Referring also to FIG. 7, the potential of Ch0 is received by the terminal on the one end side of the first integrated circuit 20a, and the potential of ChN/2 is received by the terminal on the other end side. The terminal on the other end side of the first integrated circuit 20a where the potential of ChN/2 is received is electrically connected to the terminal on the one end side of the second integrated circuit 20b via the printed circuit of the circuit board 21, and the potential of ChN/2 is also received by the terminal on the one end side of the second integrated circuit 20b. The potential of ChN is received by a terminal on the other end side of the second integrated circuit 20b.

Here, a requirement for reduction in the size of the detection unit 3 in the X direction that is the lamination direction of the cell laminate 10 is relaxed as compared to the Z direction related to reduction in the height of the battery pack 1. When the detection unit 3 is laminated together with the plurality of cells 11, in consideration of efficient pattern formation of the first printed circuit 23a and the second printed circuit 23b, a multilayer board is preferably used as the circuit board 21, the first integrated circuit 20a is mounted on the first surface 21a of the circuit board 21, and the second integrated circuit 20b is mounted on the second surface 21b of the circuit board 21.

The circuit board 21 is implemented by laminating a first layer 25a, a second layer 25b, and a third layer 25c in this order. An exposed surface of the first layer 25a serving as the first surface 21a of the circuit board 21, a boundary between the first layer 25a and the second layer 25b, a boundary between the second layer 25b and the third layer 25c, and an exposed surface of the third layer 25c serving as the second surface 21b of the circuit board 21 are pattern forming surfaces.

The first printed circuit 23a that connects the first wiring group 4a to the first integrated circuit 20a and the second integrated circuit 20b includes a first pattern P1 that transmits potentials of Ch0, Ch2, . . . , ChN/2 to be received by the first integrated circuit 20a, and a second pattern P2 that transmits potentials of ChN/2+2, ChN/2+4, . . . , ChN to be received by the second integrated circuit 20b. The first pattern P1 is provided on the same pattern forming surface S1 as the first surface 21a of the circuit board 21 where the first integrated circuit 20a is mounted, extends toward the first side in the Y direction of the circuit board 21, and is connected to the first connector 22a. The second pattern P2 is provided on a pattern forming surface S2 at the boundary between the second layer 25b and the third layer 25c, extends toward the first side in the Y direction of the circuit board 21, and is connected to the first connector 22a.

The second printed circuit 23b that connects the second wiring group 4b to the first integrated circuit 20a and the second integrated circuit 20b includes a third pattern P3 that transmits potentials of Ch1, Ch3, . . . , ChN/2-1 to be received by the first integrated circuit 20a, and a fourth pattern P4 that transmits potentials of ChN/2+1, ChN/2+3, . . . , ChN/2-1 to be received by the second integrated circuit 20b. The third pattern P3 is provided on a pattern forming surface S3 at the boundary between the first layer 25a and the second layer 25b, extends toward the second side in the Y direction of the circuit board 21, and is connected to the second connector 22b. The fourth pattern P4 is provided on the same pattern forming surface S4 as the second surface 21b of the circuit board 21 where the second integrated circuit 20b is mounted, extends toward the second side in the Y direction of the circuit board 21, and is connected to the second connector 22b.

In this way, the first pattern P1, the second pattern P2, the third pattern P3, and the fourth pattern P4 are provided on the pattern forming surfaces S1, S2, S3, and S4 different from each other, and thus intersections among the first pattern P1, the second pattern P2, the third pattern P3, and the fourth pattern P4 are eliminated. Accordingly, the first wiring group 4a located on the first side can be connected to the first side of the circuit board 21, the second wiring group 4b located on the second side can be connected to the second side of the circuit board 21 separately from the first wiring group 4a, and thus the cell laminate 10 and the detection unit 3 can be efficiently connected.

The circuit board 21 of the detection unit 3 shown in FIGS. 6 and 7 can also be a multilayer board where the first layer 25a, the second layer 25b, and the third layer 25c are laminated in this order.

Although the embodiment of the present invention has been described above, the present invention is not limited to the above-described embodiment, and modifications, improvements, and the like can be made as appropriate. In the present specification, at least the following matters are described. In the parentheses, the corresponding constituent elements and the like in the above embodiment are shown, but the present invention is not limited thereto.
(1) A battery pack including:
a battery (battery 2) including a plurality of cells (cells 11) connected in series;
a detection unit (detection unit 3) including an integrated circuit (integrated circuit 20) that detects a voltage of each of the plurality of cells, and a circuit board (circuit board 21) where the integrated circuit is mounted; and
a wiring group (wiring group 4) configured to connect the battery and the detection unit, in which
each of the plurality of cells is flat, has a positive electrode at one end in a first direction orthogonal to a thickness direction, and has a negative electrode at the other end in the first direction,
the plurality of cells are laminated in the thickness direction with the first direction of each of the cells aligned in parallel, and are laminated such that disposition of the positive electrode and the negative electrode of each of the cells is alternately inverted,
the detection unit is disposed adjacent to a laminate of the plurality of cells in a second direction orthogonal to the thickness direction and the first direction, or is laminated together with the plurality of cells,
the wiring group includes
   a first wiring group (first wiring group 4a) connected to a potential detection location located on a first side in the first direction of the laminate of the plurality of cells, among a plurality of potential detection locations that are one end and the other end of series connection of the plurality of cells, and a midpoint between the cells that are adjacent in a connection order, and
   a second wiring group (second wiring group 4b) connected to a potential detection location located on a second side opposite from the first side in the first direction of the laminate of the plurality of cells, among the plurality of potential detection locations,
the circuit board includes
   a first printed circuit (first printed circuit 23a) that electrically connects the first wiring group and the integrated circuit, and
   a second printed circuit (second printed circuit 23b) that electrically connects the second wiring group and the integrated circuit,
the first printed circuit and the second printed circuit are provided on different pattern forming surfaces of the circuit board,
the first printed circuit extends to the first side in the first direction of the circuit board, and
the second printed circuit extends to the second side in the first direction of the circuit board.

According to the battery pack of the above (1), the first printed circuit and the second printed circuit are provided on different pattern forming surfaces of the circuit board, and thus an intersection between the first printed circuit extending to the first side in the first direction of the circuit board and the second printed circuit extending to the second side is eliminated. Accordingly, the first wiring group located on the first side can be connected to the first side of the circuit board, the second wiring group located on the second side can be connected to the second side of the circuit board separately from the first wiring group, and thus the battery and the detection unit can be efficiently connected.
(2) In the battery pack according to (1),
the integrated circuit includes a first integrated circuit (first integrated circuit 20a) and a second integrated circuit (second integrated circuit 20b),
the first printed circuit includes
   a first pattern (first pattern P1) that electrically connects a part of the first wiring group to the first integrated circuit, and
   a second pattern (second pattern P2) that electrically connects a remaining part of the first wiring group to the second integrated circuit,
the second printed circuit includes
   a third pattern (third pattern P3) that electrically connects a part of the second wiring group to the first integrated circuit, and
   a fourth pattern (fourth pattern P4) that electrically connects a remaining part of the second wiring group to the second integrated circuit,
the first pattern is provided on a first pattern forming surface (first pattern forming surface S1) of the circuit board,
the second pattern is provided on a second pattern forming surface (second pattern forming surface S2) of the circuit board,
the third pattern is provided on a third pattern forming surface (third pattern forming surface S3) of the circuit board, and
the fourth pattern is provided on a fourth pattern forming surface (fourth pattern forming surface S4) of the circuit board.

According to the battery pack of the above (2), it is possible to efficiently connect the battery and the detection unit.
(3) In the battery pack according to the above (2),
the detection unit is disposed adjacent to the laminate of the plurality of cells in the second direction, and
the first integrated circuit and the second integrated circuit are mounted on one surface of the circuit board.

According to the battery pack of the above (3), a height of the battery pack can be reduced.
(4) In the battery pack according to (3),
the detection unit is adjacent to a central portion in a lamination direction of the laminate of the plurality of cells.

According to the battery pack of the above (4), it is possible to efficiently connect the battery and the detection unit.
(5) In the battery pack according to the above (2),
the detection unit is laminated together with the plurality of cells,
the first integrated circuit is mounted on one surface of the circuit board, and
the second integrated circuit is mounted on another surface of the circuit board.

According to the battery pack of the above (5), it is possible to efficiently connect the battery and the detection unit.
(6) In the battery pack according to the above (5),
the detection unit is inserted into a central portion in a lamination direction of the laminate of the plurality of cells.

According to the battery pack of the above (6), it is possible to efficiently connect the battery and the detection unit.
(7) In the battery pack according to any one of (1) to (6),
each of the first wiring group and the second wiring group is a ribbon cable or is formed on a flexible printed circuit board.

According to the battery pack of the above (7), it is possible to efficiently connect the battery and the detection unit.

### REFERENCE SIGNS LIST

1: battery pack
2: battery
3: detection unit
4: wiring group
4a: first wiring group
4b: second wiring group
10: cell laminate
11: cell
20: integrated circuit
20a: first integrated circuit
20b: second integrated circuit
21: circuit board
22a: first connector
22b: second connector
23a: first printed circuit
23b: second printed circuit
24: via
25a: first layer
25b: second layer
25c: third layer
P1: first pattern
P2: second pattern
P3: third pattern
P4: fourth pattern
S1: pattern forming surface
S2: pattern forming surface
S3: pattern forming surface
S4: pattern forming surface

What is claimed is:

1. A battery pack comprising:
a battery including a plurality of cells connected in series;
a detection unit including an integrated circuit that detects a voltage of each of the plurality of cells, and a circuit board where the integrated circuit is mounted; and
a wiring group configured to connect the battery and the detection unit, wherein
each of the plurality of cells is flat, has a positive electrode at one end of the each of the plurality of cells in a first direction orthogonal to a thickness direction of the each of the plurality of cells, and has a negative electrode at other end of the each of the plurality of cells in the first direction,
the plurality of cells are laminated in the thickness direction with the first direction of each of the cells aligned in parallel, such that an arrangement of the positive electrode and the negative electrode of each of the cells is alternately inverted,
the detection unit is disposed adjacent to a laminate of the plurality of cells in a second direction orthogonal to the thickness direction and to the first direction, or is laminated together with the plurality of cells,
the wiring group includes
a first wiring group connected to a potential detection location located on a first side, in the first direction, of the laminate of the plurality of cells, among a plurality of potential detection locations that are one end and other end of series connection of the plurality of cells, and a midpoint between the cells that are adjacent in a connection order, and
a second wiring group connected to a potential detection location located on a second side, opposite from the first side in the first direction, of the laminate of the plurality of cells, among the plurality of potential detection locations,
the circuit board includes
a first printed circuit that electrically connects the first wiring group and the integrated circuit, and
a second printed circuit that electrically connects the second wiring group and the integrated circuit,
the first printed circuit and the second printed circuit are provided on different pattern forming surfaces of the circuit board,
the first printed circuit extends to the first side in the first direction of the circuit board, and
the second printed circuit extends to the second side in the first direction of the circuit board.

2. The battery pack according to claim 1, wherein
the integrated circuit includes a first integrated circuit and a second integrated circuit,
the first printed circuit includes
a first pattern that electrically connects a part of the first wiring group to the first integrated circuit, and
a second pattern that electrically connects a remaining part of the first wiring group to the second integrated circuit,
the second printed circuit includes
a third pattern that electrically connects a part of the second wiring group to the first integrated circuit, and
a fourth pattern that electrically connects a remaining part of the second wiring group to the second integrated circuit,
the first pattern is provided on a first pattern forming surface of the circuit board,
the second pattern is provided on a second pattern forming surface of the circuit board,
the third pattern is provided on a third pattern forming surface of the circuit board, and
the fourth pattern is provided on a fourth pattern forming surface of the circuit board.

3. The battery pack according to claim 2, wherein
the detection unit is disposed adjacent to the laminate of the plurality of cells in the second direction, and
the first integrated circuit and the second integrated circuit are mounted on one surface of the circuit board.

4. The battery pack according to claim 3, wherein
the detection unit is adjacent to a central portion in a lamination direction of the laminate of the plurality of cells.

5. The battery pack according to claim 2, wherein
the detection unit is laminated together with the plurality of cells,
the first integrated circuit is mounted on one surface of the circuit board, and
the second integrated circuit is mounted on another surface of the circuit board.

6. The battery pack according to claim 5, wherein
the detection unit is inserted into a central portion in a lamination direction of the laminate of the plurality of cells.

7. The battery pack according to claim 1, wherein
each of the first wiring group and the second wiring group is a ribbon cable or is formed on a flexible printed circuit board.

8. The battery pack according to claim 2, wherein
each of the first wiring group and the second wiring group is a ribbon cable or is formed on a flexible printed circuit board.

9. The battery pack according to claim 3, wherein
each of the first wiring group and the second wiring group is a ribbon cable or is formed on a flexible printed circuit board.

10. The battery pack according to claim 4, wherein
each of the first wiring group and the second wiring group is a ribbon cable or is formed on a flexible printed circuit board.

11. The battery pack according to claim 5, wherein
each of the first wiring group and the second wiring group is a ribbon cable or is formed on a flexible printed circuit board.

12. The battery pack according to claim 6, wherein
each of the first wiring group and the second wiring group is a ribbon cable or is formed on a flexible printed circuit board.
